(19) United States
(12) Patent Application Publication
(10) Pub. No.: US 2013/0269758 A1
(43) Pub. Date: Oct. 17, 2013

(54) FLEXIBLE SUBSTRATES, APPLICATIONS OF COMPOSITE LAYERS IN SOLAR CELLS, AND SOLAR CELLS

(71) Applicants: Chih-Cheng Lin, Hsinchu City (TW); Chyi-Ming Leu, Jhudong Township (TW)

(72) Inventors: Chih-Cheng Lin, Hsinchu City (TW); Chyi-Ming Leu, Jhudong Township (TW)

(21) Appl. No.: 13/568,258

(22) Filed: Aug. 7, 2012

(30) Foreign Application Priority Data
Apr. 16, 2012 (TW) 101113420

(51) Int. Cl. B32B 15/08; H01L 31/02; B32B 3/00; B82Y 30/00

(52) U.S. Cl. 136/252; 428/450; 428/328; 428/336; 428/141; 428/337; 977/773

(57) ABSTRACT

Disclosed is a flexible substrate, including a metal substrate and a composite layer thereon. The composite layer includes polyimide and sodium-containing silica mixed with each other, and the polyimide and the sodium-containing silica have a weight ratio of about 6:4 to 9:1. The silica and the sodium ions of the sodium-containing silica have a weight ratio of 100:0.01 to 100:2.

### CROSS REFERENCE TO RELATED APPLICATIONS

The present application is based on, and claims priority from, Taiwan (International) Application Serial Number 101113420, filed on Apr. 16, 2012, the disclosure of which is hereby incorporated by reference herein in its entirety

### TECHNICAL FIELD

The technical field relates to flexible substrates, applications of composite layers in solar cells, and solar cells.

### BACKGROUND

In thin-film solar cells, copper indium gallium diselenide (CIGS) is classified as a compound semiconductor. Polycrystalline CIGS film has a complex hetero junction system, which is different from the homo p-n junction in silicon crystalline. Compared to other thin-film solar cells, solar cells utilizing the CIGS (III-V compound semiconductor) have a wider absorption frequency and more stable properties. Under standard testing conditions, the CIGS solar cells have an optoelectronic conversion efficiency higher than that of other thin-film solar cells, and similar to the best optoelectronic efficiency of a single crystalline silicon solar cell.

If a stainless steel plate is adopted as a substrate of the CIGS solar cells, a planarization layer should be firstly formed thereon. For planarizing the layers formed on the stainless steel substrate, the stainless steel substrate surface should be pre-treated to be flat. Researches for planarization layer are still needed.

### SUMMARY

One embodiment of the disclosure provides a flexible substrate, comprising: a metal substrate; and a composite layer disposed on the metal substrate, wherein the composite layer includes polyimide and sodium-containing silica mixed with each other. The polyimide and the sodium-containing silica have a weight ratio of about 6:4 to 9:1, wherein the sodium-containing silica includes silica and sodium ions, and the silica and the sodium ions have a weight ratio of about 100:0.01 to 100:2.

One embodiment of the disclosure provides a composite layer applied to a planarization layer of a solar cell, wherein the composite layer comprises: a polyimide; and a sodium-containing silica mixed with the polyimide, and the polyimide and the sodium-containing silica have a weight ratio of about 6:4 to 9:1, wherein sodium-containing silica includes silica and sodium ions, and the silica and the sodium ions have a weight ratio of about 100:0.01 to 100:2.

One embodiment of the disclosure provides a solar cell, comprising: the described flexible substrate, a bottom electrode layer on the flexible substrate; an optoelectronic conversion layer on the bottom electrode layer; and a top electrode layer on the optoelectronic conversion layer.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross-sectional view of a flexible substrate in one embodiment of the disclosure;

FIG. 2 shows a cross-sectional view of a CIGS solar cell in one embodiment of the disclosure;

FIG. 3 shows different metal concentration corresponding to different depths of a molybdenum layer formed on a stainless steel plate in one embodiment of the disclosure; and

FIG. 4 shows different metal concentration corresponding to different depths of a molybdenum layer formed on a flexible substrate in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Firstly, a polyimide solution is prepared as described below. The polyimide is polymerized of an aromatic diamine and an aromatic dianhydride. For example, the aromatic diamine includes at least one chemical structure in Formulae 1 to 6, other suitable diamines (please referring to U.S. Pat. No. 4,764,89), or combinations thereof. The aromatic dianhydride includes at least one chemical structure in Formulae 7 to 1, other suitable dianhydrides (please refer to U.S. Pat. No. 4,764,89), or combinations thereof.

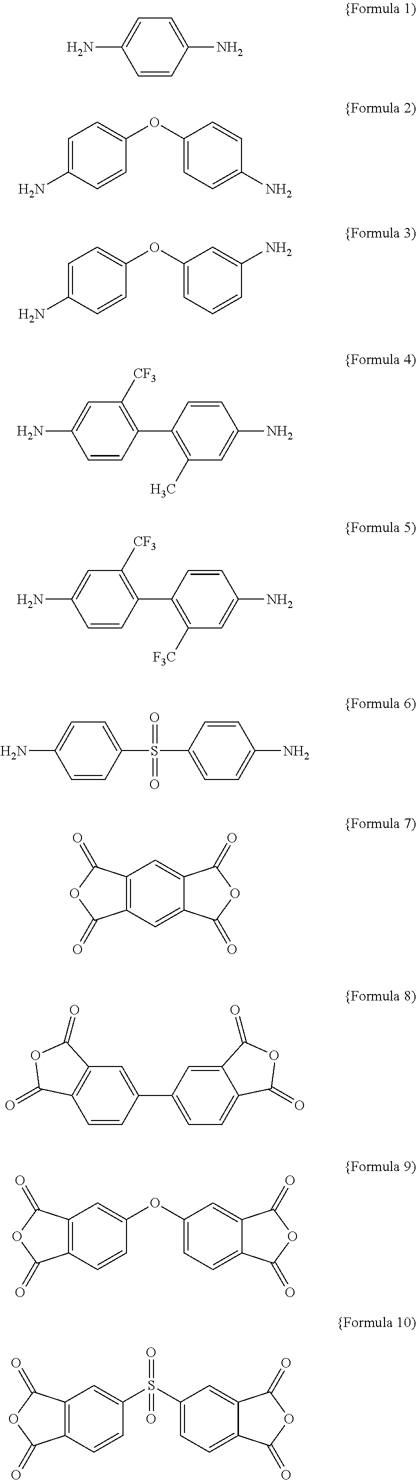

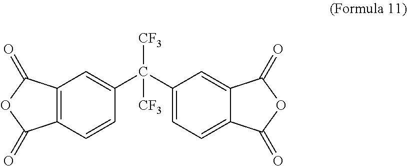 [SMILES: O=C1OC(=O)c2cc(C(c3ccc4c(c3)C(=O)OC4=O)(C(F)(F)F)C(F)(F)F)ccc21]

In one embodiment, the polyimide applied in the solar cell should have excellent thermal resistance. The monomers of the polyimide may have one or more benzene rings as shown in Formulae 1 to 11.

The aromatic diamine and the aromatic dianhydride are reacted in a polar solvent to form a precursor (polyamic acid) of the polyimide. The polar solvent can be amide, cycloketone, phenolic compound, and the like, e.g. dimethylacetamide, N-methyl-2-pyrrolidone, butyrolactone, or m-cresol. Thereafter, the precursor is imidized by a high-temperature method or a chemical reaction, such that the precursor is dehydrated and ring-closed to form a polyimide. In one embodiment, the starting materials such as diamine and dianhydride have aromatic groups, the product polyimide has excellent thermal resistance (Td higher than about 550° C.). In one embodiment, the polyimide solution has a solid content of about 15 wt % and a relative viscosity of larger than about 1000 cps. A polyimide having an overly low relative viscosity cannot form a complete film due to its low film-forming property.

Afterward, a commercially available silica solution having a pH value of 1 to 5 is provided, such as a sodium-containing silica solution 1620S commercially available from Chang Chun Chemical Co. or the sodium-containing silica solution Snowtex-O, commercially available from Nissan Chemical Co. It should be understood that not only the commercial sodium-containing silica solutions listed above but also other silica solutions free of sodium ions can be adopted. In one embodiment, the sodium-containing silica includes silica and sodium ions, and the silica and the sodium ions have a weight ratio of about 100:0.01 to 100:2. An overly low amount of the sodium ions cannot diffuse to the CIGS optoelectronic conversion layer of a CIGS solar cell. Otherwise, an overly high amount of the sodium ions will overly diffuse to the CIGS optoelectronic conversion layer, thereby reducing the optoelectronic conversion efficiency of the CIGS solar cell. In one embodiment, the silica has a size (diameter) of about 1 nm to 100 nm. Overly large silica will enhance the surface roughness of a subsequently formed composite layer.

The sodium-containing silica solution is mixed with the polyimide solution to form a composite solution. In the composite solution, the polyimide and the sodium-containing silica have a weight ratio of 6:4 to 9:1. An overly high ratio of the polyimide will give the subsequently formed composite layer insufficient thermal resistance. An overly low ratio of the polyimide will give the composite too much inorganic content to form a composite film, because the composite will be brittle.

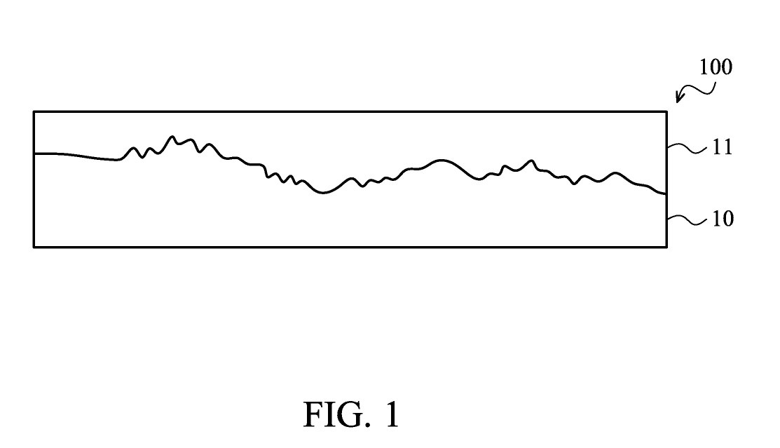

As shown in FIG. 1, a metal substrate 10 is provided. In one embodiment, the metal substrate is a commercially available stainless steel plate with a surface roughness (Ra) of largely greater than about 20 nm, and even greater than about 1 μm. In general, a stainless steel plate with a surface roughness of less than or equal to 10 nm needs additional treatments. In other embodiments, the metal substrate can be a stainless steel plate, aluminum foil, or titanium foil. The metal substrate 10 has a thickness of about 25 μm to 200 μm. An overly thick metal substrate will degrade its flexibility. An overly thin metal substrate cannot effectively support the layered structure formed thereon.

The composite solution is then coated on the metal substrate 10, and the solvent of the composite solution is removed to obtain a composite layer 1. As such, a flexible substrate 100 is completed. The coating method includes spin coating, spray coating, slit coating, dip coating, another suitable coating, or combinations thereof. The solvent can be removed by air drying, low pressure (e.g. vacuum), heating, or combinations thereof. In one embodiment, the composite has a thickness of 5 μm to 20 μm. An overly thin composite layer cannot totally cover surface bumps on the metal substrate 10. An overly thick composite layer cannot further reduce the surface roughness of the flexible substrate, but increases the material cost of the composite layer. The composite layer has a surface roughness of less than or equal to 10 nm (for example, about 0 nm to 10 nm), which is much less than the original surface roughness of the metal substrate. As such, the other layers can be formed on the composite layer with a lower surface roughness. In other words, the composite layer may serve as a planarization layer for the other layers formed thereon. In addition, the composite layer may resist chemicals (e.g. acidic or basic etchant) in the following processes. The composite layer also resists high temperature (Td greater than about 550° C.) and therefore benefits in the following high temperature processes. Accordingly, the flexible substrate of the disclosure can be applied in several flexible electronic products.

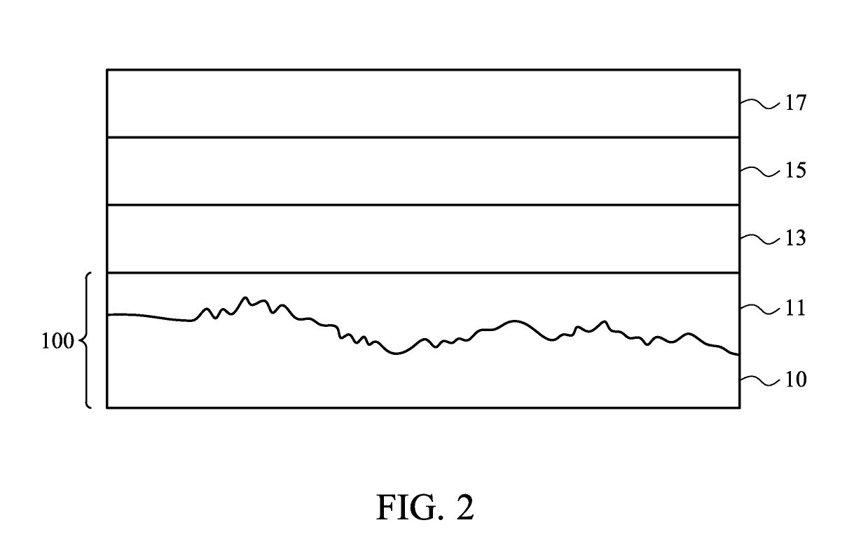

Take a CIGS solar cell for example, a bottom electrode layer 13, a CIGS optoelectronic conversion layer 15, and a top electrode layer 17 can be sequentially formed on the composite layer 1 of the flexible substrate 100, as shown in FIG. 2. The materials and methods of forming the bottom electrode layer 13, the CIGS optoelectronic conversion layer 15, and the top electrode layer 17 can be found in US 2009194150A1. During high-temperature selenization, the composite layer 1 may prevent the metal ions of the metal substrate 10 from diffusing into the bottom electrode layer 13 to influence the conductivity of the bottom electrode layer 13. In addition, the sodium ions of the composite layer 1 will diffuse into the CIGS optoelectronic conversion layer 15 to further enhance its optoelectronic conversion efficiency.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout

### EXAMPLES

### Example 1

### Synthesis of Polyimide Solution

20.42 g of the diamine in Formula 2 (0.102 mole) was stirred and dissolved in 201.67 g of dimethylacetamide (DMAc), and 30 g of the dianhydride in Formula 7 (0.102 mole) was then added to the diamine solution and stirred for 8 hours at room temperature, thereby obtaining a gold-yellow viscous polyimide solution. Finally, 84.04 g of DMAc was added to the polyimide solution, such that the polyimide solution was tuned to have a solid content of 15 wt % and a viscosity of 32300 cps.

### Example 2

### Flexible Substrate

30 g of the polyimide solution (solid content of 15 wt %) in Example 1 and 9.64 g of sodium-containing silica solution Snowtex-O (solid content of 20 wt %, commercially available from Nissan Chemical Co.) were mixed and stirred to be uniformly dispersed for forming a composite solution. The composite solution was spin coated on a stainless steel plate (SUS304 with stainless 1.4301 standard, thickness of 100 μm, and surface roughness Ra>20 nm). The composite coating was baked at a temperature of 350° C. to form a composite layer on the stainless steel plate. The composite layer had a thickness of 10 μm and a sodium-containing silica content of 30.84 wt %, wherein the silica and the sodium ions have a weight ratio of 100:0.17. As measured by thermogravimetric analysis, the composite layer had a thermal decomposition temperature (Td) of 581.68° C., higher than the selenization temperature (550° C.) of the CIGS optoelectronic conversion layer. As measured by atomic force microscopy (AFM), the composite layer had a surface roughness (Ra) of 4.68 nm greatly less than the surface roughness (>20 nm) of the stainless steel plate.

### Example 3

### Synthesis of Polyimide Solution

11.02 g of the diamine in Formula 1 (0.102 mole) was stirred and dissolved in 164.08 g of dimethylacetamide (DMAc), and 30 g of the dianhydride in Formula 8 (0.102 mole) was then added to the diamine solution and stirred for 8 hours at room temperature, thereby obtaining a black viscous polyimide solution. Finally, 68.37 g of DMAc was added to the polyimide solution, such that the polyimide solution was tuned to have a solid content of 15 wt % and a viscosity of 41000 cps.

### Example 4

### Flexible Substrate

30 g of the polyimide solution (solid content of 15 wt %) in Example 3 and 9.64 g of sodium-containing silica solution Snowtex-O (solid content of 20 wt %, commercially available from Nissan Chemical Co.) were mixed and stirred to be uniformly dispersed for forming a composite solution. The composite solution was spin coated on a stainless steel plate (SUS304 with stainless 1.4301 standard, thickness of 100 μm, and surface roughness Ra>20 nm). The composite coating was baked at a temperature of 350° C. to form a composite layer on the stainless steel plate. The composite layer had a thickness of 10 μm and a sodium-containing silica content of 31.94 wt %, wherein the silica and the sodium ions have a weight ratio of 100:0.17. As measured by thermogravimetric analysis, the composite layer had a thermal decomposition temperature (Td) of 607.21° C., higher than the selenization temperature (550° C.) of the CIGS optoelectronic conversion layer.

Subsequently, several chemicals for manufacturing CIGS solar cells were selected to measure the chemical resistance of the flexible substrate. The flexible substrate was dipped in bromine water for 10 seconds, and then dipped in KCN solution for 20 minutes. Gallium was then plated on the flexible substrate at a pH value of 13, and CdS was then deposited on the flexible substrate. After the above treatments, the composite layer and the stainless steel substrate still had excellent adhesion, without corrosion or peeling.

As measured by atomic force microscopy (AFM), the composite layer had a surface roughness (Ra) of 4.947 nm, much less than the surface roughness (>20 nm) of the stainless steel plate.

### Example 5

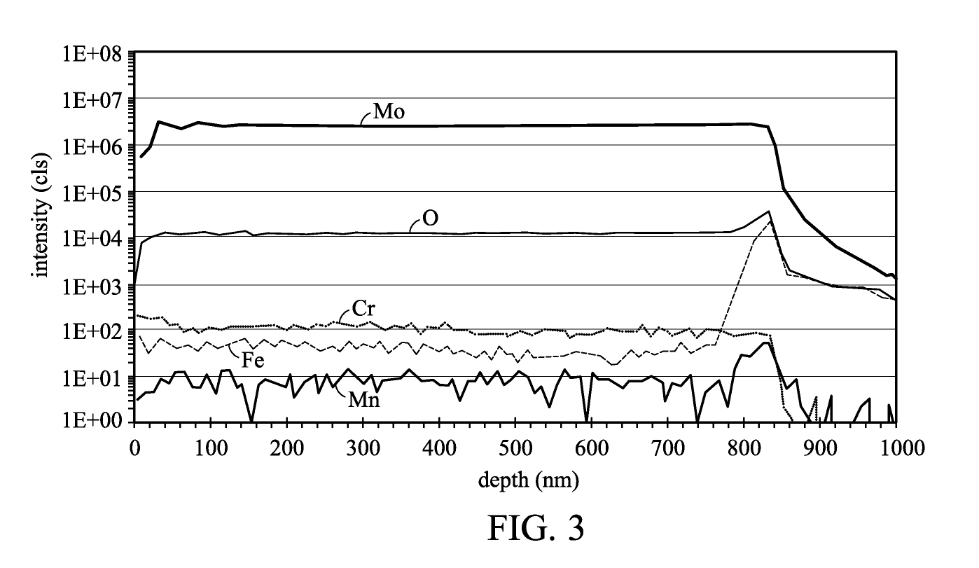

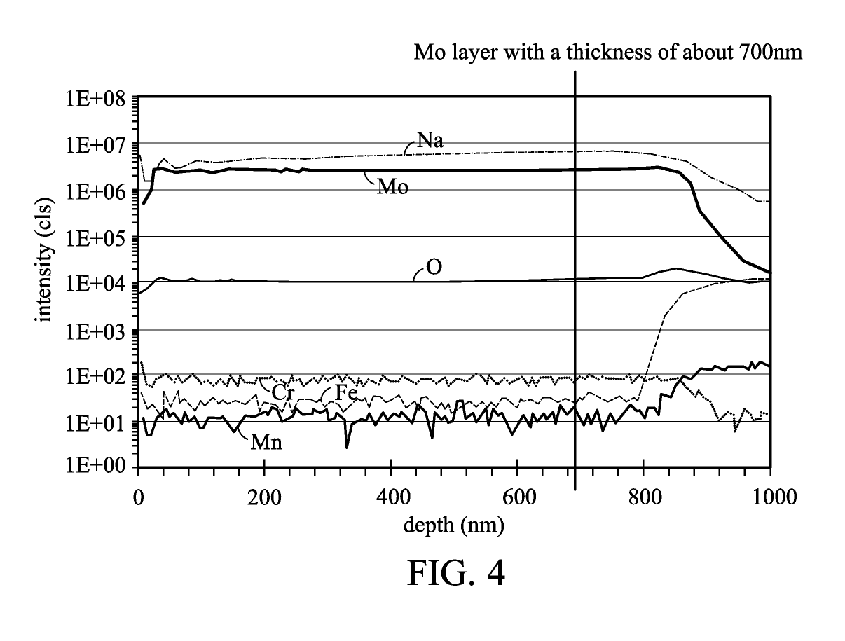

A molybdenum layer with a thickness of 700 nm was deposited on a stainless steel plate (stainless 1.4301 standard) and the flexible substrate in Example 4, respectively. The above layered structures were annealed under nitrogen at 520° C. for 10 minutes, and the different metal concentrations of different depths (downward from the molybdenum layer surface) were measured by secondary ion mass spectrometry. In FIG. 3, the molybdenum layer was directly formed on the stainless steel plate. In FIG. 4, a composite layer was disposed between the stainless steel plate and the molybdenum layer. As shown in FIG. 3, the metal ions such as Cr, Fe, or Mn ions of the stainless steel plate diffused into the molybdenum layer when the molybdenum layer was directly formed on the stainless steel plate. As shown in FIG. 4, the metal ion concentrations of Cr, Fe, and Mn in the molybdenum layer was largely reduced when the composite layer was disposed between the stainless steel plate and the molybdenum layer. Accordingly, the composite layer had an insulation effect. Furthermore, the sodium ions of the composite layer diffused into the molybdenum layer. If a CIGS optoelectronic conversion layer was further formed on the molybdenum layer, the sodium ions should diffuse into the CIGS optoelectronic conversion layer and enhance its optoelectronic conversion efficiency.

As shown in this example, the sodium ions of the sodium-containing silica in the composite layer might diffuse into the CIGS optoelectronic conversion layer, and the metal ions of the metal substrate would be insulated by the composite layer without diffusing into the bottom electrode layer.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A flexible substrate, comprising:
a metal substrate; and
a composite layer disposed on the metal substrate,
wherein the composite layer includes polyimide and sodium-containing silica mixed with each other, and the polyimide and the sodium-containing silica have a weight ratio of about 6:4 to 9:1,
wherein the sodium-containing silica includes silica and sodium ions, and the silica and the sodium ions have a weight ratio of about 100:0.01 to 100:2.

2. The flexible substrate as claimed in claim 1, wherein the sodium-containing silica has a size of 1 nm to 100 nm.

3. The flexible substrate as claimed in claim 1, wherein the polyimide is copolymerized of an aromatic diamine and an aromatic dianhydride.

4. The flexible substrate as claimed in claim 1, wherein the composite layer has a thickness of 5 μm to 20 μm.

5. The flexible substrate of claim 1, wherein the composite layer has a surface roughness of less than or equal to 10 nm.

6. The flexible substrate as claimed in claim 3, wherein the aromatic diamine includes at least one chemical structure of Formulae 1 to 6:

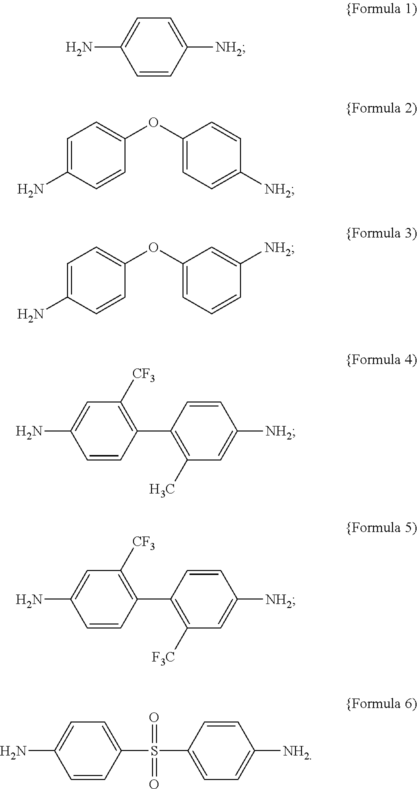 [SMILES: Nc1ccc(N)cc1 ; Nc1ccc(Oc2ccc(N)cc2)cc1 ; Nc1ccc(Oc2cccc(N)c2)cc1 ; Cc1cc(N)ccc1-c1ccc(N)cc1C(F)(F)F ; Nc1ccc(-c2ccc(N)cc2C(F)(F)F)c(C(F)(F)F)c1 ; Nc1ccc(S(=O)(=O)c2ccc(N)cc2)cc1]

7. The flexible substrate as claimed in claim 3, wherein the aromatic dianhydride includes at least one chemical structure of Formulae 7 to 1:

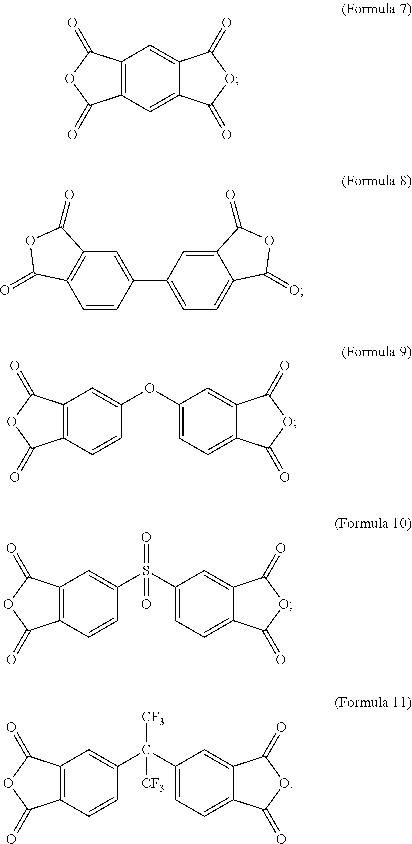 [SMILES: O=c1oc(=O)c2cc3c(=O)oc(=O)c3cc12 ; O=C1OC(=O)c2cc(-c3ccc4c(c3)C(=O)OC4=O)ccc21 ; O=C1OC(=O)c2cc(Oc3ccc4c(c3)C(=O)OC4=O)ccc21 ; O=C1OC(=O)c2cc(S(=O)(=O)c3ccc4c(c3)C(=O)OC4=O)ccc21 ; O=C1OC(=O)c2cc(C(c3ccc4c(c3)C(=O)OC4=O)(C(F)(F)F)C(F)(F)F)ccc21]

8. The flexible substrate as claimed in claim 1, wherein the metal substrate has a thickness of 25 μm to 200 μm.

9. A composite layer applied to a planarization layer of a solar cell, wherein the composite layer comprises:
a polyimide; and
a sodium-containing silica mixed with the polyimide, and the polyimide and the sodium-containing silica have a weight ratio of about 6:4 to 9:1,
wherein sodium-containing silica includes silica and sodium ions, and the silica and the sodium ions have a weight ratio of about 100:0.01 to 100:2.

10. The composite layer of claim 9, wherein the sodium-containing silica has a size of 1 nm to 100 nm.

11. A solar cell, comprising:
the flexible substrate as claimed in claim 1,
a bottom electrode layer on the flexible substrate;
an optoelectronic conversion layer on the bottom electrode layer; and
a top electrode layer on the optoelectronic conversion layer.
